(19) United States
(12) Patent Application Publication
(10) Pub. No.: US 2022/0128500 A1
(43) Pub. Date: Apr. 28, 2022

(54) INDUCTIVE MEASURING APPARATUS AND CALIBRATION DEVICE AND METHOD

(71) Applicant: Forschungszentrum Jülich GmbH, Jülich (DE)

(72) Inventors: Xihe Tan, Julich (DE); Egon Zimmermann, Inden/Altdorf (DE); Achim Mester, Koln (DE); Jan van der Kruk, LR Vaals (NL); Walter Glaas, Elsdorf (DE); Markus Dick, Baesweiler (DE); Michael Ramm, Huchem-Stammeln (DE)

(21) Appl. No.: 17/297,953

(22) PCT Filed: Oct. 30, 2019
(86) PCT No.: PCT/EP2019/079606

§ 371 Date: Dec. 20, 2021

(30) Foreign Application Priority Data
Nov. 29, 2018 (DE) 10 2018 220 532.9

(51) Int. Cl. G01N 27/02; G01D 5/20

(52) U.S. Cl. CPC G01N 27/025; G01D 5/2006

(57) ABSTRACT

The invention relates to a measuring device having a transmitter (1, 2, 3) for transmitting a measurement signal, a receiver (4) for receiving a response to the transmitted measurement signal, and a signal processing device (7, 8, 9; 18) for determining a measurement result from the response, the transmitter and/or the receiver having a coil (3; 4; 16), the measuring device having a calibration device for reducing an interference influence on the measurement result, characterized in that the calibration device is configured such that a current pulse can be introduced into the coil (3; 4; 16) from a current source (DC) and the signal processing device (7, 8, 9; 18) can perform a measurement value correction using the calibration signal generated by the current pulse and can determine a measurement result from the response and the measurement value correction.

The invention further relates to a measuring method.

The invention relates to a measuring device having a transmitter for transmitting a measuring signal, a receiver for receiving a response to the transmitted measuring signal and a signal processing device for determining a measurement result from the response. The transmitter and/or the receiver comprise at least one coil. The measuring device comprises a calibration device for reducing an interference influence on the measurement result. The invention further relates to a method for operating the measuring device.

A measuring device with a transmitter for transmitting a measuring signal and a receiver for receiving a response to the transmitted measuring signal for locating and identifying metallic ammunition bodies below the earth's surface is known from the publication DE 197 31 560 A1. A time-varying magnetic field is generated as a measurement signal by means of a transmitter coil of the transmitter. Through this an eddy current can be generated in a ferromagnetic ammunition body and thus a secondary field in response. This induces a locating signal in the receiver coils of the receiver, which is evaluated.

According to EP 1 289 147 A1, an excitation signal is generated as a measurement signal by an oscillating circuit in a measuring device of the type described above. The excitation signal can be influenced by the approach or presence of an object. This influence is determined by a receiver of the measuring device. The determined response is evaluated by the measuring device.

The publication DE 10 2009 026 403 A1 also discloses a measuring device with a transmitter for transmitting a measuring signal and a receiver for receiving a response to the transmitted measuring signal. The transmitter comprises a primary circuit which includes a transmitter coil. The receiver comprises a secondary circuit having a receiver coil. There is a short-circuit path through which the transmitter coil can be inductively coupled to the receiver coil for diagnostic purposes.

The publication WO 2018/014891 A1 describes a calibration method for electromagnetic induction measuring systems as well as a device suitable therefor. A calibration method is provided which, for ground measurements of apparent electrical conductivity, takes into account influences which are attributable to the measuring device itself or which come from the environment and which influence the measurement. The method allows the individual calibration of an electrical induction system, which takes into account environmental influences. For calibration, an induction measuring device with at least one transmitter and at least one receiver is set up in at least two heights above the ground to be measured and the apparent electrical conductivities are calculated in a forward model and then optimized in an inversion method.

EP 2 657 726 A2 discloses a method for electromagnetic measurement of the electrical conductivity of a medium. A magnetic alternating field (primary field) is applied to the medium by a transmitter coil, so that currents are induced in the medium and form a further magnetic alternating field (secondary field), wherein the secondary field is measured by a receiver coil and the conductivity of the medium is evaluated from this.

According to the invention, the primary field is measured directly or indirectly at the location of the transmitter coil and from this the contribution of the primary field to the field at the location of the receiver coil is evaluated. Due to the superposition principle, the contributions of the primary field and the secondary field to the total field at the location of the secondary coil overlap without interference. The voltage induced in the secondary coil, which serves as the measurement signal, depends linearly on this total field. Therefore, the contribution of the primary field and thus its temperature-dependent drift can be corrected out if the primary field at the location of the transmitter coil and the spatial arrangement of the transmitter and receiver coils relative to each other are known.

From the publication DE 10 2012 203 111 A1 a method and a device for MRI imaging is known. From the publication US 2010/0241389 A1 a system and a method in connection with MRI excitation is known. A wireless sensor is disclosed in the publication US 2011/0115497 A1. The invention known from the publication US 2005/0190100 A1 relates to weather radar calibration. A method for controlling a magnetic resonance system is known from the publication DE 10 2011 083 959 A1. Publication US 2012/0139776A1 discloses a method for obtaining calibration parameters for antennas.

The present invention is intended to enable particularly accurate measurements to be made with little technical effort by means of a measuring device of the aforementioned type.

The task is solved by a measuring device with the features of the first claim. For solving the task, a method comprises the features of the additional claim. Advantageous embodiments result from the subclaims.

A measuring device comprises a transmitter for transmitting a measuring signal, a receiver for receiving a response to the transmitted measuring signal and a signal processing device. The signal processing device is configured such that it can be used to determine a sought measurement result from the response. The transmitter and/or the receiver have a coil. A calibration device is present to be able to reduce an interference influence on the measurement result. The calibration device is configured such that a current pulse is introduced into the coil from a current source. A calibration signal is generated by the introduction of a current pulse. The signal processing device performs a measured value correction using the calibration signal generated by the current pulse. The calibration signal includes information about an interference influence by the coil. “Measurement correction” means that this interference influence is determined by the signal processing device and a result is output as the measurement result that no longer comprises this determined interference. With little technical effort, a measurement result is obtained in which distorting interferences are reduced. Measurement results can therefore be determined particularly accurately.

Advantageously, the calibration device is configured such that a measurement is interrupted and the current pulse is introduced into the coil during the interruption. “Interrupt” means that a measurement pause is inserted. After the measurement pause has elapsed, the measurement is therefore continued. In this way, interfering influences can be determined in the course of a measurement. This makes it possible to determine measurement results particularly accurately in an improved manner. A measurement can be interrupted by temporarily switching off the transmitter and consequently not sending a measurement signal then.

In one embodiment, the calibration device comprises a switching device configured such that the current pulse can be introduced into the coil by switching on and subsequently switching off the switching device. By technically simple means, the current pulse can thus be generated. It is thus also possible by technically simple means to introduce a current pulse into the coil during a measurement pause.

Advantageously, the signal processing device is configured such that it uses as a calibration signal a signal generated by the coil after the switching device is switched off and before a measurement is performed or continued. Thus, in this embodiment, the calibration signal is a response following the current pulse introduced into the coil. This contributes further in an improved manner to be able to determine a measurement signal particularly accurately.

The switching device preferably comprises a DC voltage source and a first electrical resistor. The DC voltage source is connected to the first electrical resistor. By this it is meant that there is an electrical conductor which is electrically connected to the DC voltage source on the one hand and to the first electrical resistor on the other hand, so that a current can flow from the DC voltage source to the first electrical resistor. The electrical conductor may be or comprise a wire consisting of metal. The electrical conductor may be a conductor track of a circuit board. The electrical conductor may consist of copper.

The first electrical resistor is connected to a second electrical resistor through an electrical conductor so that a current can flow from the DC voltage source through the first resistor to the second electrical resistor. The second electrical resistor is connected to the coil by an electrical conductor so that the current can flow from the first electrical resistor through the second electrical resistor into the coil.

The electrical connection or the electrical conductor between the first and second electrical resistor is electrically connected to ground via a switch using electrical conductors. When the switch is closed, current flows from the DC source to ground. When the switch is open, current cannot flow from the DC source to ground. This then flows to the coil. If the switch is opened and then closed again, a current pulse is introduced into the coil.

The switching device comprises a microcontroller which is configured such the opening and closing of the switch can be controlled by the microcontroller.

Overall, this switching device is capable of introducing a current pulse into the coil in a suitable manner within a short measurement pause in order to be able to generate a calibration signal.

The first electrical resistor is advantageously at least 1000000 times larger than the short-circuit resistance of the switch, in order to be able to discharge the current almost completely via the closed switch, so that it does not flow via the second resistor. The short-circuit resistance is advantageously smaller than 10 mΩ. The first electrical resistor can be 10 kΩ to 30 kΩ.

The second electrical resistor is advantageously greater than the first resistor. The second electrical resistor can be 100 kΩ to 300 kΩ.

The signal processing device is advantageously configured such that it adapts a predetermined oscillation equation to the calibration signal during operation.

Parameters of the oscillation equation are determined through the adaptation. A correction value is determined from the parameters using a frequency equation. In this way, the signal processing device can determine a measurement signal corrected by a correction value.

Advantageously, a calibration device controls a measurement in such a way that a measurement is recurrently interrupted and during each interruption the calibration device introduces a current pulse into the coil. Temporal changes of interfering influences can thus be continuously taken into account. It is thus possible to determine a measurement result in an improved manner.

The transmitter may comprise an electrical voltage source by means of which a voltage can be applied to a coil of the transmitter or to an electrical oscillating circuit of the transmitter to generate a magnetic or an electromagnetic measurement signal. The transmitter and/or receiver may comprise one or more coils. The signal processing device may comprise an amplifier by means of which the response is amplified.

The signal processing device may comprise an analog-to-digital converter with which the response may be digitized. The signal processing device may comprise a processor with which the response is evaluated. The signal processing device may comprise an output device with which a processed response, i.e. a measured value, is output.

The measuring device can be configured such that it determines a phase difference between measuring signal and response and to evaluate the determined phase difference. The measuring device can be configured such that it can be used to analyze a subsoil (subsurface). The measuring device can be configured in such a way that with it a measure of the electrical conductivity of a subsoil can be determined.

The output device may comprise a monitor and/or a speaker to output the processed response. The output device may comprise a data interface through which the processed response may be transmitted to another device.

The measuring device may be configured to measure the apparent electrical conductivity of soils. The measuring device may be configured such that it allows for investigation of a near-surface soil to a depth of, for example, 40 meters or 50 meters.

A measuring device suitable for this purpose typically comprises a transmitter with a coil, also called “transmitter coil”, and a receiver with one or more coils, also called “receiver coil(s)”. There is a predetermined distance between the transmitter coil and the one or more receiver coils. By exciting the transmitter coil with an alternating current in the frequency range of typically between 100 Hz to 100 kHz, a magnetic field can be generated, also referred to as the primary field. Due to the electrical conductivity of the soil, induction currents are caused by the primary field, which in turn cause a magnetic field called the secondary field. The secondary field is usually several orders of magnitude smaller than the primary field. The receiver can measure both fields together to determine the apparent electrical conductivity (ECa) of a soil.

Interfering influences can affect the accuracy of a measurement result. Such interfering influences may be due to temperature effects or noise, for example. The present invention can reduce such interfering influences. Measurement results can thus be improved.

Each coil can lead to interfering influences. The present invention makes it possible to at least reduce any interfering influence of any coil. A measuring device according to the invention can be scaled accordingly.

Other components such as analog-to-digital converters can also lead to temperature-dependent interfering influences. In order to also reduce such interfering influences, there are preferably temperature sensors for the corresponding components, with which the temperatures of the respective component are measured. The interfering influence as a function of temperature can be known, for example, from calibration measurements. The respective interfering influence can thus be determined by means of measured temperatures. On this basis, further correction values can be generated for the respective components. These correction values are also preferably used to obtain a measured value that is as far as possible not distorted by such interfering influences.

The invention also relates to a method for operating a measuring device, in which a measurement is interrupted at least once, preferably several times, within a second, a calibration signal is generated within each measurement pause in order to determine measurement results involving the calibration signals. Thus, interfering influences are determined continuously. Measurement results are obtained which are not influenced by these interfering influences. It is therefore possible to make particularly accurate measurements without having to invest excessive effort.

The figures show:

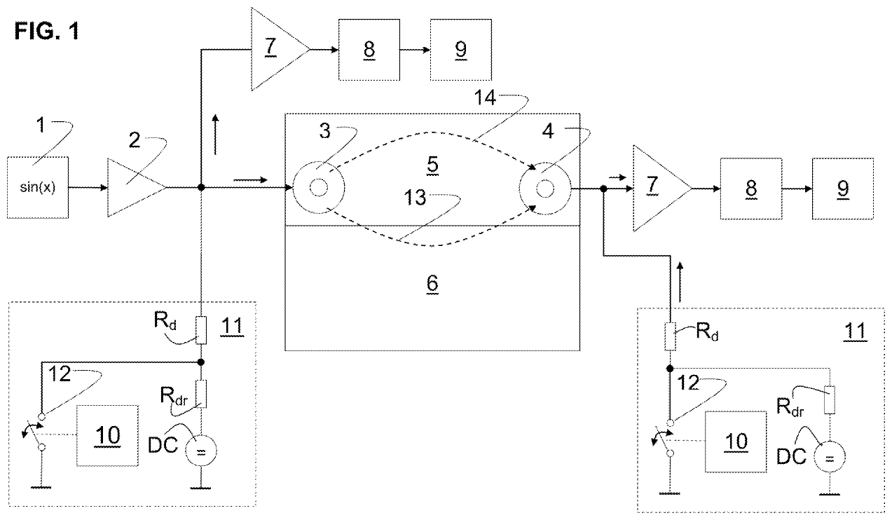

FIG. 1: Block diagram of a measuring device;

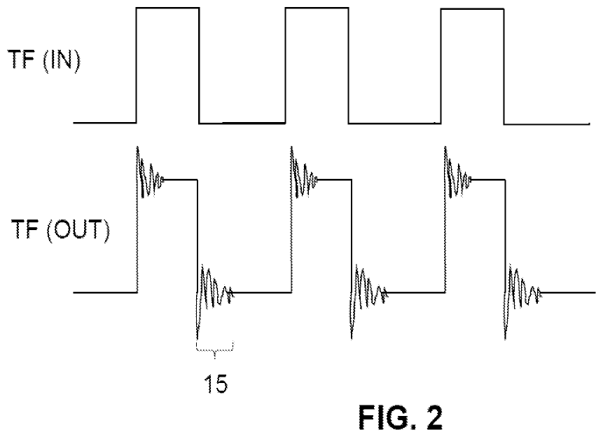

FIG. 2: current pulses and resulting calibration signals;

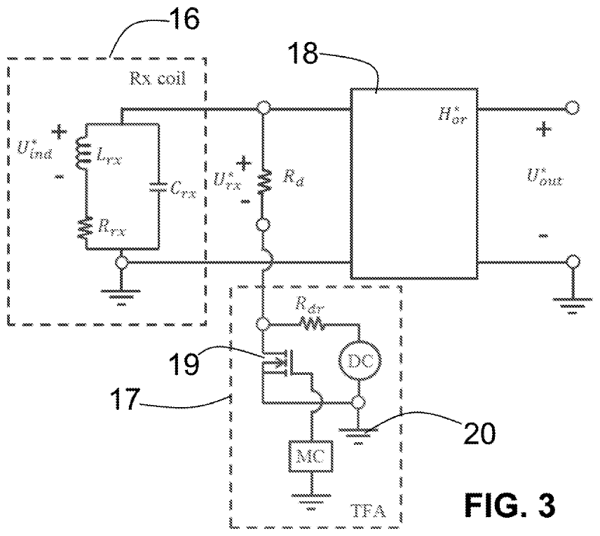

FIG. 3: calibration device

As shown in FIG. 1, the measuring device may comprise an AC power source with an AC generator 1 and an electronic amplifier 2. The transmitter may have a transmitter coil 3. The receiver may have a receiver coil 4. The transmitter coil 3 and receiver coil 4 may be spatially separated from each other. Transmitter coil 3 and receiver coil 4 may be located in air 5 above a ground 6 to allow examination of the ground 6.

A signal processing device connected to the transmitter coil 3 may comprise an electronic amplifier 7, an analog-to-digital converter 8, and a signal processor 9. The signal processor 9 may comprise a microcontroller. A calibration device may comprise a control 10, a component assembly or circuit 11, and an electrical switch 12 to enable an electrical pulse to be applied to the receiver coil 4.

For a measurement, an alternating current can be introduced into the transmitter coil 3 by the alternating current source 1, 2. The transmitter coil 3 thereby generates an electromagnetic wave. A part 13 of the electromagnetic wave passes through the ground 6 and thus reaches the receiver coil 4. A part 14 of the electromagnetic wave reaches the receiver coil 4 exclusively through the air 5. The ground 6 causes a phase shift of the part 13 relative to the part 14. This phase shift provides a measure for characterizing the ground 6. A response is induced in the receiver coil 4 by the electromagnetic wave 13, 14. The response is passed to the signal processing device 7, 8, 9, which determines a measured value from the response.

For example controlled by a control, the AC source 1, 2 can be temporarily switched off. Within a measurement pause thus created, a current pulse can be introduced into the receiver coil 4 controlled by the control 10. The control 10 can, for example, open and close the switch 12 so as to introduce a current pulse into the receiver coil 4. This may be done periodically. For example, FIG. 2 shows rectangular current pulses TF(IN) periodically introduced into the receiver coil 4 during measurement pauses. This causes the receiver coil 4 to generate a response TF(OUT) shown in FIG. 2. The portion 15 of the response TF(OUT) can now be used as a calibration signal. The calibration signal 15 temporally follows the end of a current pulse. Temporally after the end of a calibration signal, a measurement can be continued, i.e. the AC source 1, 2 can be switched on again, for example. The calibration signal 15 can be a damped oscillation as shown in FIG. 2.

The signal processing device 7, 8, 9 processes both a measurement signal originating from the receiver coil 4 and a calibration signal 15 originating from the receiver coil 4 to determine a measurement value therefrom.

A calibration device may also be provided for a transmitter coil 3, as is shown in FIG. 1. If a transmitter or a receiver comprises a plurality of coils, a further calibration device may be provided for each additional coil. The measuring device is scalable in this sense.

For example, the following oscillation function TFA(t), which depends on the time t, can be adapted to the calibration signal 15 by the signal processing devices 7, 8, 9.

TFA(t)=Ae^{-+t}Re(e^{j(ω}^{_{d}}^{t+ϕ)})+B.

The parameters determined in this way can be inserted into the following frequency function:

$${G}_{TFA} ( j ω ) = \frac{j ω + α}{{( j ω + α )}^{2} + {ω}_{d}^{2}} .$$

The value G_{TFA}(jω) determined in this way is a measure of the phase shift caused by the coil and can therefore be a correction value. This measure can be taken into account when the measured value is determined by the signal processing device 7, 8, 9.

FIG. 3 shows further possible details. Shown is an equivalent circuit diagram 16 for a coil “Rx coil”, a switching device 17 and a signal processing device 18. The switching device 17 comprises a DC voltage source DC. The DC voltage source DC is connected to a first electrical resistor R_{dr} through an electrical conductor. The first electrical resistor R_{dr} is connected to a second electrical resistor R_{d} through an electrical conductor. The first electrical resistor R_{dr} may be 20 kΩ. The second electrical resistor R_{d} may be 200 kΩ. The electrical conductor between the first electrical resistor R_{dr} and the second electrical resistor R_{d} is connected to an electrical switch 19, which can be opened and closed controlled by a microcontroller MC. When the electrical switch 19 is closed, an electrical current flows from the DC voltage source DC to ground 20. When the electrical switch 19 is opened and closed again under the control of the microcontroller MC, an electrical pulse is applied to the coil Rx coil as shown in FIG. 2.

### LIST OF REFERENCE SIGNS

1: AC generator
2: Amplifier/electronics
3: Transmitter coil
4: Receiver coil
5: Air
6: Ground
7: Amplifier/electronics
8: ADC, analog-to-digital converter
9: Signal processor
10: Control
11: TFA
12: Switch
13: Electromagnetic wave
14: Electromagnetic wave
15: Calibration signal
16: Equivalent circuit diagram for a coil “Rx coil”
17: Switching device
18: Signal processing device
19: Switch
20: Ground
Dc: DC voltage source
R_{dr}: First electrical resistor
R_{d}: Second electrical resistor

1. Measuring device having a transmitter (1, 2, 3) for transmitting a measurement signal, a receiver (4) for receiving a response to the transmitted measurement signal and a signal processing device (7, 8, 9; 18) for determining a measurement result from the response, the transmitter and/or the receiver having a coil (3; 4; 16), the measuring device having a calibration device for reducing an interference influence on the measurement result, characterized in that the calibration device is configured such that a current pulse can be introduced into the coil (3; 4; 16) from a current source (DC) and the signal processing device (7, 8, 9; 18) can perform a measurement value correction using the calibration signal generated by the current pulse and can determine a measurement result from the response and the measurement value correction.

2. Measuring device according to claim 1, characterized in that the calibration device is configured such that during the interruption of a measurement the current pulse is introduced into the coil (3; 4; 16).

3. Measuring device according to one of the preceding claims, characterized in that the calibration device comprises a switching device (17) configured such that the current pulse can be introduced into the coil (3; 4; 16) by switching on and subsequently switching off the switching device (17).

4. Measuring device according to the preceding claim, characterized in that the signal processing device (7, 8, 9; 18) is configured such that it processes as a calibration signal a signal generated by the coil (3; 4; 16) after the switching device (17) is switched off and before a measurement is performed.

5. Measuring device according to one of the two preceding claims, characterized in that the switching device (17) comprises a DC voltage source (DC) connected to a first electrical resistor (R_{dr}) and the first electrical resistor (R_{dr}) is connected to a second electrical resistor (R_{d}) and the second electrical resistor (R_{d}) is connected to the coil (3; 4; 16) and the electrical connection between the first and second electrical resistors (R_{dr}, R_{d}) is connected to ground (20) via a switch (19), so that, current flows from the direct current source (DC) to ground (20) when the switch (20) is closed and current flows from the direct current source (DC) to the coil (3; 4; 16) when the switch (19) is open, and the switching device (17) comprises a microcontroller (MC) which is configured such that the opening and closing of the switch (19) can be controlled by the microcontroller (MC).

6. Measuring device according to the preceding claim, characterized in that the first electrical resistor (R_{dr}) is advantageously 1000000 times greater than a short-circuit resistance of the switch (19).

7. Measuring device according to the preceding claim, characterized in that the second electrical resistor (R_{d}) is greater than the first resistor (R_{dr}).

8. Measuring device according to one of the three preceding claims, characterized in that the first electrical resistor (R_{dr}) is 10 kΩ to 30 kΩ and/or the second electrical resistor (R_{d}) is 100 kΩ to 300 kΩ.

9. Measuring device according to one of the four preceding claims, characterized in that the short-circuit resistance of the switch (19) is less than 10 mΩ.

10. Measuring device according to one of the preceding claims, characterized in that the signal processing device (7, 8, 9; 18) is configured such that during operation it adapts a predetermined oscillation equation to the calibration signal and thereby determines parameters of the oscillation equation and determines a correction value from the parameters using a frequency equation and determines a measurement signal corrected by the correction value.

11. Measuring device according to one of the preceding claims, characterized in that the calibration device controls a measurement in such a way that a measurement is recurrently interrupted and during each interruption the calibration device introduces a current pulse into the coil (3; 4; 16).

12. Measuring device according to one of the preceding claims, characterized in that one or more temperature sensors are present, by means of which the temperature of one or more components is measured and one or more correction values are determined on the basis of measured temperatures and by means of the signal processing device (7, 8, 9; 18) a measurement result can also be determined taking into account the one or more further correction values.

13. Method for operating a measuring device according to one of the preceding claims, characterized in that within one second a measurement is interrupted at least once, preferably several times, within each measurement pause a calibration signal is generated in order to determine measurement results involving the calibration signals.
